(19) United States
(12) Patent Application Publication
(10) Pub. No.: US 2026/0075955 A1
(43) Pub. Date: Mar. 12, 2026

(54) DIODE FOR ELECTROSTATIC DISCHARGE PROTECTION

(71) Applicant: Taiwan Semiconductor Manufacturing Company, Ltd., Hsinchu (TW)

(72) Inventors: Chun-Ting Chen, Hsinchu (TW); Chih-Pin Hung, Hsinchu (TW); Chin-Hsun Pan, Kaohsiung (TW); Hui Yu Chiang, Taoyuan (TW); Tzu-Heng Chang, New Taipei (TW); Ting-Yi Li, Hsinchu (TW)

(21) Appl. No.: 18/828,433

(22) Filed: Sep. 9, 2024

(51) Int. Cl. H01L 27/02

(52) U.S. Cl. CPC H10D 89/611

(57) ABSTRACT

An electrostatic discharge (ESD) protection diode includes a P-type layer and an N-type layer in contact with the P-type layer to form a P/N junction at an interface therebetween. The P/N junction is non-planar. In one fabrication approach, dopant implantation is performed to form N-type wells in the P-type layer, which overlap or are contiguous with the N-type layer and increase a surface area of the P/N junction. The ESD protection diode may also have an anode and a cathode. The integrated circuit (IC) being protected may have first and second power distribution networks disposed on opposite sides of the IC that connect with the IC to electrically power the IC, and the ESD protection diode is disposed between the power distribution networks with the cathode being part of one power distribution network and the anode being part of the other power distribution network.

### BACKGROUND

The following relates to the electrostatic discharge (ESD) protection arts, semiconductor fabrication arts, integrated circuit (IC) arts, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a side sectional view of an electrostatic discharge (ESD) protection diode for providing electrostatic discharge protection, according to one nonlimiting illustrative embodiment.

FIGS. 2A, 2B, and 2C diagrammatically show top, side sectional, and bottom views, respectively, of the ESD protection diode of FIG. 1 with the anode, cathode, and oxide regions omitted.

FIGS. 3A and 3B diagrammatically show cut C-C indicated in FIG. 2B in accordance with two nonlimiting illustrative embodiments.

FIG. 4 diagrammatically shows a side sectional view of an integrated circuit protected by the ESD protection diode of FIG. 1.

FIG. 5 diagrammatically illustrates a side sectional view of an ESD protection diode for providing electrostatic discharge protection, according to another nonlimiting illustrative embodiment.

FIGS. 6A, 6B, and 6C diagrammatically show top, side sectional, and bottom views, respectively, of the ESD protection diode of FIG. 5 with the anode, cathode, and oxide regions omitted.

FIG. 7 diagrammatically shows a side sectional view of an integrated circuit protected by the ESD protection diode of FIG. 5.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Disclosed herein are embodiments of a diode suitably used in providing electrostatic discharge (ESD) protection for integrated circuits. An ESD protection diode is connected across a power input to an integrated circuit (where “integrated circuit” as used herein encompasses a complete integrated circuit, or a portion, i.e. sub-circuit, thereof), with the ESD protection diode connected across the power input in reverse bias. In the reverse biased arrangement, the ESD protection diode normally does not conduct electrical current (or, more precisely, conducts a leakage current which is deemed negligible). The breakdown voltage of the ESD protection diode is designed such that, in before an electrostatic charge can build up to a magnitude large enough that it could damage the integrated circuit, the breakdown voltage of the ESD protection diode is exceeded, at which point the ESD protection diode enters electrical breakdown and conducts a large electrical current thereby discharging the built-up electrostatic charge (i.e., providing electrostatic discharge to protect the integrated circuit). Thus, in operation the ESD protection diode limits the peak voltage to approximately the breakdown voltage of the ESD protection diode, and provides a low-resistance path to ground for electrostatic discharge if excessive electrostatic charge accumulates. Excessive electrostatic charge can be introduced in numerous ways, such as by contact of the integrated circuit with another object that carries a high electrostatic charge, e.g., during handling, packaging, or assembly processes.

There are numerous design goals for an ESD protection diode. One design goal is to maximize the electrical conductivity (or, equivalently, minimize the electrical resistance) of the ESD protection diode after it enters electrical breakdown. This can somewhat analogously be quantified as the on-state current of the ESD protection diode, that is, the magnitude of the electrical current that flows once the ESD protection diode has entered its breakdown state. Maximizing the on-state current maximizes the effectiveness of the ESD protection provided by the ESD protection diode. If the on-state current is too low, then the electrostatic charge buildup may not be discharged fully, and/or may not be discharged fast enough, to provide effective ESD protection for the integrated circuit.

Another design goal is to minimize the leakage current conducted by the ESD protection diode in its normal reverse biased state (that is, when it has not entered breakdown). Minimizing the leakage current minimizes standby power consumed by the ESD protection diode, and thus also minimizes unnecessary heat generation by the ESD protection diode.

Another design goal for an ESD protection diode is do ensure the breakdown voltage is high enough to ensure that the ESD protection diode does not prematurely enter the breakdown state. Put another way, the ESD protection diode should not enter the breakdown state in the absence of an electrostatic charge buildup that is high enough to present a danger of damage to the protected integrated circuit.

Yet another design goal is to minimize the die area or footprint of the ESD protection diode. This is beneficial to minimize the area occupied by the ESD protection diode and thereby maximize the available die area for the functional integrated circuit.

Disclosed herein are ESD protection diodes according to various embodiments that advantageously facilitate achieving these diverse design goals. In one disclosed aspect, the P/N junction of the ESD protection diode is nonplanar. This advantageously provides a larger effective area for the P/N junction without a concomitant increase in the die area or footprint of the ESD protection diode. The larger effective area of the nonplanar P/N junction also advantageously increases the on-state current (or, somewhat analogously, increases conductivity or equivalently reduces resistance of the ESD protection diode that has entered its breakdown state).

In another disclosed aspect, the P-type region of the ESD protection diode has a P-type doping gradient in which a P-type doping concentration increases with increasing distance away from the P/N junction. Additionally or alternatively, the N-type region of the ESD protection diode has an N-type doping gradient in which an N-type doping concentration increases with increasing distance away from the P/N junction. The doping gradient(s) advantageously provide smaller leakage current and hence lower standby power, and advantageously increase the breakdown voltage of the ESD protection diode.

In another disclosed aspect, the ESD protection diode includes an N-type region contact in contact with the N-type region, a P-type region contact in contact with the P-type region, an anode in contact with the N-type region contact, and a cathode in contact with the P-type region contact. The P-type region and the N-type region are disposed between the N-type region contact and the P-type region contact, and the P-type region and the N-type region are disposed between the anode and the cathode. This vertical arrangement places the anode/P-type region contact and the cathode/N-type region contact on opposite sides of the P/N junction, which advantageously reduces the electrical resistance (or, equivalently, increases the electrical conductivity) and increases the on-state current of the ESD protection diode. The arrangement also reduces the height of the ESD protection diode.

In another disclosed aspect, the P-type region contact is a single region, rather than being a plurality of contact regions; and likewise the N-type region contact is a single region, rather than being multiple contact regions. This aspect advantageously reduces the electrical resistance (or, equivalently, increases the electrical conductivity) and increases the on-state current of the ESD protection diode.

It is contemplated that a given embodiment of an ESD protection diode may include one, two, more, or all of these disclosed aspects.

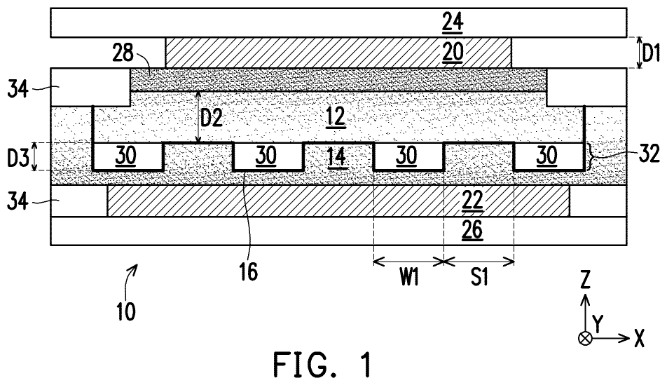

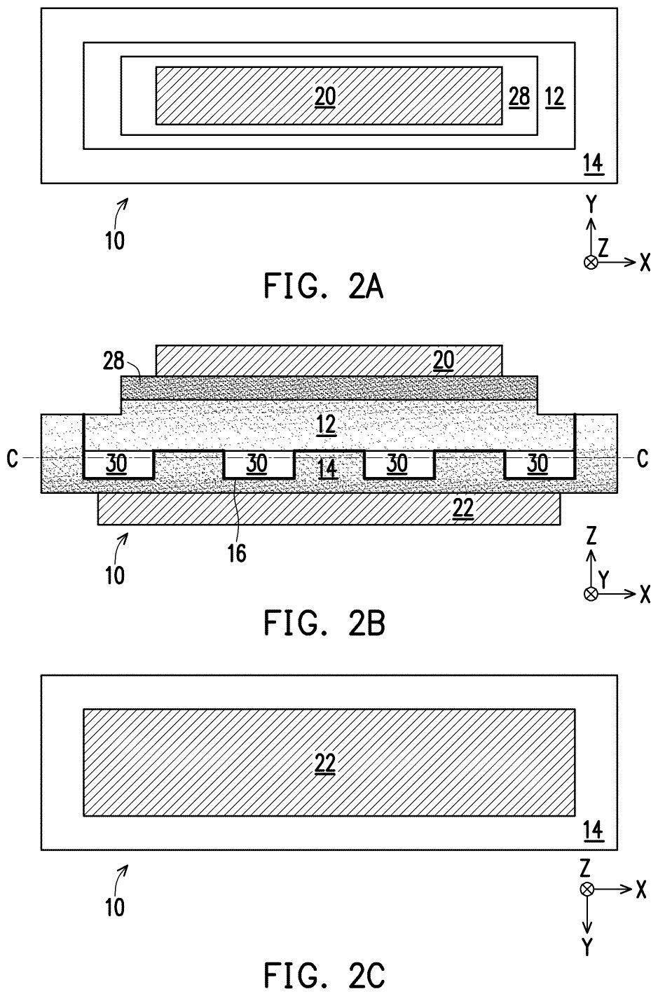

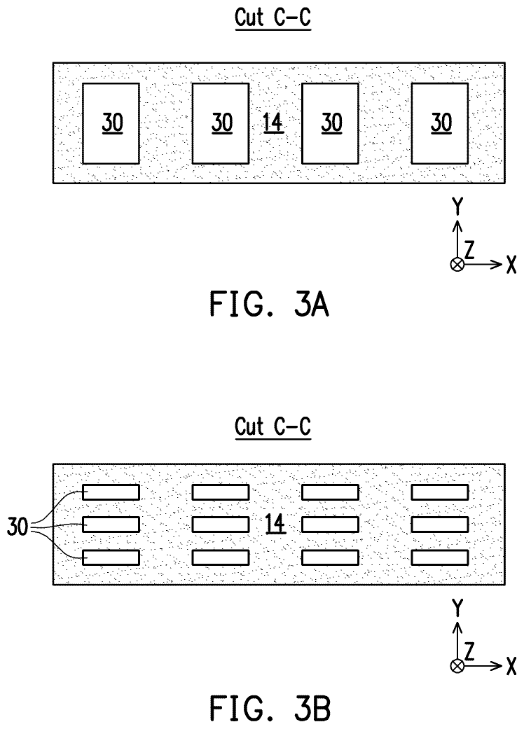

With reference to FIG. 1 and FIGS. 2A, 2B, and 2C and FIGS. 3A and 3B, an ESD protection diode 10 according to a first nonlimiting illustrative embodiments is described. FIG. 1 diagrammatically illustrates a side sectional view of the ESD protection diode 10. FIGS. 2A, 2B, and 2C diagrammatically show top, side sectional, and bottom views, respectively, of the ESD protection diode 10 of FIG. 1 with the anode, cathode, and oxide regions omitted. FIGS. 3A and 3B diagrammatically show cut C-C indicated in FIG. 2B in accordance with two nonlimiting illustrative embodiments. FIGS. 1, 2A, 2B, 2C, 3A, and 3B each include indicated reference X-Y-Z directions.

The ESD protection diode 10 includes an N-type region or layer 12, and a P-type region or layer 14. The N-type region or layer 12 is in contact with the P-type region or layer 14 to form a P/N junction 16 at an interface between the N-type region or layer 12 and the P-type region or layer 14. As seen in the side sectional views of FIG. 1 and FIG. 2B, the P/N junction 16 is non-planar. The ESD protection diode 10 further includes an N-type region contact 20 in contact with the N-type region 12, and a P-type region contact 22 in contact with the P-type region 14. As further shown only in FIG. 1, a cathode 24 is in contact with the N-type region contact 20, and an anode 26 is on contact in contact with the P-type region contact 22. In the nonlimiting illustrative example, a more heavily N-type doped region or layer 28 (i.e., N⁺-doped region or layer 28) is interposed between the N-type region 12 and the N-type region contact 20. The interposed N⁺-doped region or layer 28 reduces contact resistance between the N-type region 12 and the N-type region contact 20.

The N-type region or layer 12 and the P-type region or layer 14 are suitably silicon regions or layers, although other semiconductor materials are contemplated, such as silicon germanium alloy (Si₁₋ₓGeₓ), gallium arsenide (GaAs), or so forth. In the case of silicon, suitable N-type dopants for the N-type regions or layers of the ESD protection diode 10 include (but are not limited to) nitrogen (N), phosphorous (P), arsenic (As), or antimony (Sb); and suitable P-type dopants for the P-type regions or layers of the ESD protection diode 10 include (but are not limited to): boron (B), boron difluoride (BF₂), or indium (In). In one suitable fabrication approach, the P-type region 14 is formed as a P-type well (PW) by P-type dopant implantation into a silicon base material such as a silicon wafer or the silicon layer of a silicon-on-insulator (SOI) substrate, and the N-type region is formed as an N-type well (NW) by N-type counter-doping by dopant implantation into the P-type well.

To provide the nonplanar P/N junction 16, an additional N-type doping implantation is performed to form deep N-type wells 30 (i.e., DNWs 30) in the P-type layer 14. This dopant implant step employs a photolithographically patterned mask to delineate the lateral areas of the deep N-type wells 30. The N-type wells 30 overlap or are contiguous with the N-type layer 12, and thus increase a surface area of the P/N junction 16. With reference to FIGS. 3A and 3B which diagrammatically show cut C-C through the DNWs 30 as indicated in FIG. 2B in accordance with two nonlimiting illustrative embodiments, the N-type wells 30 formed by the N-type dopant implantation into the P-type region or layer 14 may constitute a one-dimensional array of N-type wells 30 as shown in FIG. 3A, or may constitute a two-dimensional array of N-type wells 30 as shown in FIG. 3B. Other layouts of the N-type wells 30 are contemplated, including layouts in which the N-type wells 30 do not form linear or rectilinear arrays. Moreover, while FIGS. 3A and 3B illustrate the N-type wells 30 as having rectangular perimeters, it is alternatively contemplated for the N-type wells 30 to have other perimeter shapes, such as oval, hexagonal, or so forth. The layout and perimeters of the deep N-type wells 30 are suitably delineated by the photolithography mask used to pattern the photoresist layer used in the deep N-type dopant implantation step that forms the deep N-type wells 30.

Referring back to FIGS. 1 and 2B, the illustrative N-type wells 30 have a rectangular cross-section in the X-Z plane. However, more generally the N-type wells 30 may have rounded shapes or other nonlinear shapes in the X-Z plane to provide the desired nonplanar P/N junction 16. In some embodiments, parameters of the deep dopant implantation (e.g., dose, beam current/implant time) or of an optional post-implantation anneal are adjusted to provide a desired depth distribution and hence shape in the X-Z plane of the deep N-type wells 30.

It will be appreciated that the foregoing is merely a nonlimiting illustrative example of one suitable fabrication sequence for forming the N-type region or layer 12 and 30 and P-type region or layer 14, and other fabrication workflows are contemplated such as forming the doped regions or layers 12 and 14 by epitaxial deposition and/or dopant diffusion (or counter-diffusion). As previously discussed, the nonplanar P/N junction 16 of the ESD protection diode 10 advantageously provides a larger effective area for the P/N junction 16 without a concomitant increase in the die area or footprint of the ESD protection diode 10, thus advantageously increasing the on-state current and conductivity of the ESD protection diode 10 when it has entered its breakdown state. Described another way, the N-type region 12, 28, 30 and the P-type region 14 are interdigitated at the P/N junction 16 along at least one direction (as in the example of FIG. 3A) and optionally along two directions (as in the example of FIG. 3B), and this interdigitation causes the P/N junction 16 to be nonplanar. Described yet another way, the N-type region 12, 28, 30 and the P-type region 14 are intermeshed in a transition region 32 (along the Z direction using the reference X-Y-Z directions; the transition region 32 is labeled only in FIG. 1), and this intermeshing causes the P/N junction 16 to be nonplanar.

With particular reference to FIGS. 1 and 2B, in the illustrative ESD protection diode 10, the P-type region 14 has a P-type doping gradient in which a P-type doping concentration increases with increasing distance away from the P/N junction 16; and likewise, the N-type region 12 has an N-type doping gradient in which a N-type doping concentration increases with increasing distance away from the P/N junction 16. As previously discussed, these doping gradients advantageously provide smaller leakage current for the ESD protection diode 10, and hence provide lower standby power. The gradients also advantageously increase the breakdown voltage of the ESD protection diode 10.

By way of nonlimiting illustration, in an example in which the material are silicon, the N-type doping concentration of the N⁺ layer 28 may be in a range of about 1×10¹⁵ cm⁻³ to about 9×10¹⁶ cm⁻³, the N-type doping concentration of the N-type layer 12 may be in a range of about 1×10¹³ cm⁻³ to about 9×10¹⁴ cm⁻³, with the N-type doping distal from the P/N junction 16 (and proximate to the N⁺ layer 28) being at or near the upper end of this range and the N-type doping proximate to the P/N junction 16 (including the DNWs 30) being at or near the lower end of this range. In some nonlimiting illustrative examples, the N-type doping concentration of the N-type layer 12 distal from the P/N junction 16 is about 90 times larger than the N-type doping of the N-type layer 12 proximate to the P/N junction 16. In some nonlimiting illustrative examples, the N-type doping concentration of the N-type layer 12 distal from the P/N junction 16 is at least 80 times larger than the N-type doping of the N-type layer 12 proximate to the P/N junction 16. The P-type doping concentration of the P-type layer 14 may be in a range of about 1×10¹³ cm⁻³ to about 9×10¹⁴ cm⁻³, with the P-type doping distal from the P/N junction 16 (and proximate to the P-type region contact 22) being at or near the upper end of this range and the P-type doping proximate to the P/N junction 16 being at or near the lower end of this range. In this nonlimiting illustrative example: the N⁺ layer 28 may have a thickness D1 in a range of 0.1 micron to 1 micron; the N-type region or layer 12 may have a thickness D2 in a range of 0.1 micron to 1 micron; the DNWs 30 may have a thickness D3 (corresponding to the transition 32 along the Z direction indicated only in FIG. 1) of 0.1 micron to 1 micron; and the P-type region or layer 14 may have a thickness in a range of 0.1 micron to 1 micron. Again, there are merely nonlimiting examples, and doping concentrations and/or thicknesses outside of these illustrative ranges are contemplated. In this nonlimiting illustrative example: the DNWs 30 may have a width W1 of 0.1 micron to 1 micron, and the DNWs 30 may have a spacing S1 of 0.1 micron to 1 micron. Again, there are merely nonlimiting examples, and widths and/or spacings outside of these illustrative ranges are contemplated. More generally, the P/N junction 16 has a non-smooth junction topography - in the illustrative example this is achieved by the DNWs 30. In the nonlimiting illustrative example, D3/W1 (i.e., the ratio of the thickness to width of the DNW 30) is in a range of 0.1 to 10.

The N-type region contact 20 and P-type region contact 22 can, by way of some nonlimiting illustrative examples, be copper, aluminum, titanium, tantalum, cobalt, tungsten, various alloys thereof, polysilicon, a metal nitride such as tantalum nitride (TaN) or titanium nitride (TiN), and/or so forth. The choice of contact material may made based on design factors such as, by way of nonlimiting illustrative example, employing a same material for the contacts 20 and 22 as is used for source and drain contacts of FETs, finFETs, GAA-FETs, or the like used in the integrated circuit for which ESD protection is provided, or employing a same material for the contacts as is used for vias of a metallization stack formed during back end-of-line (BEOL) processing of the integrated circuit. The contact 20 to the N-type region or layer 12 and the contact 22 to the P-type region or layer 14 may be made of the same material, or may be made of different materials. The ESD protection diode 10 may include other features not shown, and/or features such as oxide regions 34 (shown only in FIG. 1) for delineating the active area of the ESD protection diode 10. The oxide regions 34 may, for example, be formed as shallow trench isolation (STI) regions.

As seen in FIG. 2A which shows a top view of the illustrative ESD protection diode 10 (with the cathode 24 omitted), the N-type region contact 20 in contact with the N-type region 12, 28 is a single region. As seen in FIG. 2C which shows a bottom view of the illustrative ESD protection diode 10 (with the anode 26 omitted), the P-type region contact 22 in contact with the P-type region 14 is a single region. In the illustrative example, the N-type region contact 20 is a single simply connected region which has no holes in it, and likewise the P-type region contact 22 is a single simply connected region which has no holes in it. As previously discussed, these single-region contacts 20 and 22 advantageously reduce contact resistance as compared with having multiple contact regions, thereby increase the on-state electric current conducted by the ESD protection diode 10 which improves the efficacy of the ESD protection provided by the ESD protection diode 10.

Referring to FIGS. 1 and 2B, it is also seen that the N-type region 12, 28, 30 and the P-type region 14 (and hence also the P/N junction 16 therebetween) are disposed between the N-type region contact 20 and the P-type region contact 22. As shown only in FIG. 1, it is further seen that the N-type region 12, 28, 30 and the P-type region 14 (and hence also the P/N junction 16 therebetween) are disposed between the cathode 24 and the anode 26. Moreover, the N-type region contact 20 and the P-type region contact 22 are disposed between the cathode 24 and the anode 26. As previously discussed, this vertical arrangement places the cathode 24/N-type region contact 20 and the anode 26/P-type region contact 22 on opposite sides of the P/N junction 16, which advantageously reduces the electrical resistance (or, equivalently, increases the electrical conductivity) and increases the on-state current of the ESD protection diode 10. The vertical arrangement also reduces the height of the ESD protection diode.

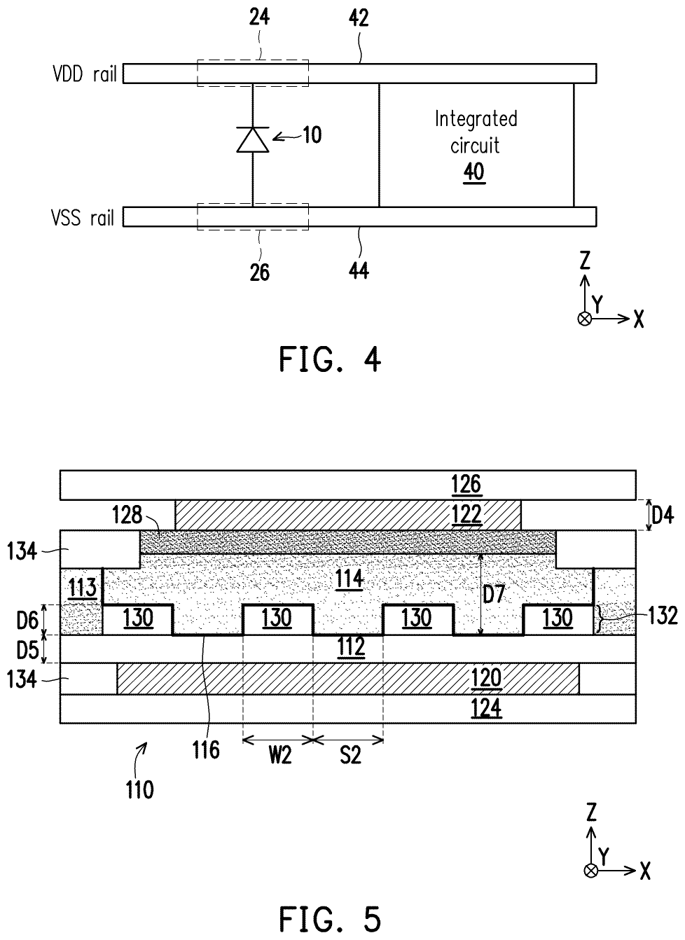

With continuing reference to FIG. 1 and with further reference now to FIG. 4, implementation according to one nonlimiting illustrative example of electrostatic discharge protection using the ESD protection diode 10 is described. FIG. 4 diagrammatically shows a side sectional view of an integrated circuit 40 protected by the ESD protection diode 10. FIG. 4 also includes an indication of the reference X-Y-Z directions, indicating that the side sectional view of FIG. 4 is an X-Z plane.

The integrated circuit (IC) 40 can in general include any type of semiconductor component used in IC chips or dies. By way of nonlimiting illustrative example, the integrated circuit 40 may include transistors such as planar field effect transistor (FET) devices, finFET devices, gate-all-around FET (GAA-FET) devices, various combinations thereof, and/or so forth, by way of some nonlimiting illustrative examples. The integrated circuit 40 may in general implement any functionality for which the circuitry of the integrated circuit 40 is designed, such as (by way of a few nonlimiting illustrative examples): a radio frequency (RF) circuit such as an antenna circuit, heterodyning circuit, or so forth; an audio circuit; a wired or wireless communication IC such as an Ethernet or USB transceiver or radio; a microprocessor; an electronic memory array; various combinations thereof; and/or so forth. A first power distribution network 42 is disposed on a first (e.g., front) side of the integrated circuit 40, and a second power distribution network 44 is disposed on a second (e.g., back) side of the integrated circuit 40, opposite from the first side 42 of the integrated circuit. The first power distribution network 42 and the second power distribution network 44 connect with the integrated circuit 40 to electrically power the integrated circuit 40. In the illustrative example of FIG. 4, the integrated circuit 40 is fabricated in metal-oxide-semiconductor (MOS) technology, the first (e.g., front-side) power distribution network 42 is a VDD rail providing the VDD voltage level, and the second (e.g., back-side) power distribution network 44 is a VSS rail providing the VSS voltage level. In some nonlimiting illustrative examples, the VSS voltage level is a ground, zero voltage, or other reference voltage. As further shown in FIG. 4, the ESD protection diode 10 is connected between the VDD rail 42 and the VSS rail 44, and more particularly the cathode 24 is part of the VDD rail 42 and the anode 26 is part of the VSS rail 44. The VDD and VSS power rails 42 and 44 may, by way of some nonlimiting illustrative examples, comprise aluminum, copper, tungsten, or another suitably electrically conductive material. With the orientation shown in FIG. 4, the ESD protection diode 10 is reverse-biased since the cathode 24 is part of the VDD rail 42 and hence is at the VDD voltage and the anode 26 is part of the VSS rail 44 and hence is at the VSS voltage, where voltage VDD is greater than voltage VSS (i.e., VDD>VSS). By making the cathode 24 part of the VDD rail 42 and the anode 26 part of the VSS rail 44, electrical resistance of the connections of the ESD protection diode 10 are advantageously reduced by eliminating additional conductive paths from the rails to the anode and cathode, and the overall height of the ESD protection diode 10 including the cathode 24 and anode 26 is advantageously reduced.

In some embodiments, the ESD protection diode 10 is fabricated as a well diode, e.g. by forming the doped regions by dopant implantation into a base material such as a silicon wafer or the silicon layer of an SOI wafer. Such a well diode is readily integrated into IC manufacturing workflows employing planar FET technology, finFET technology, GAA-FET technology, combinations thereof, or so forth.

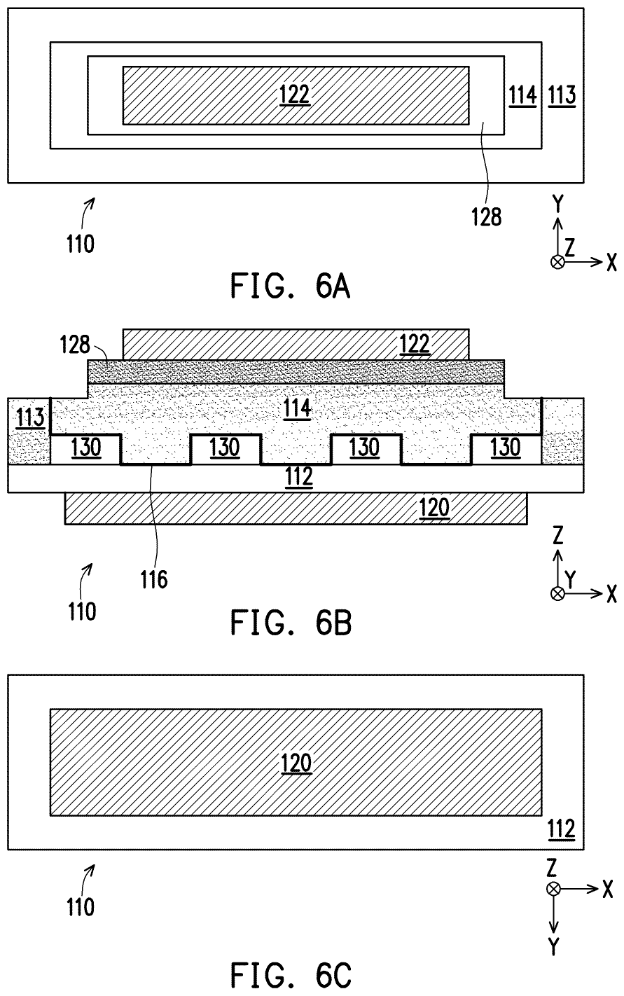

With reference to FIG. 5 and FIGS. 6A, 6B, and 6C, an ESD protection diode 110 according to a second nonlimiting illustrative embodiments is described. FIG. 5 diagrammatically illustrates a side sectional view of the ESD protection diode 110. FIGS. 6A, 6B, and 6C diagrammatically show top, side sectional, and bottom views, respectively, of the ESD protection diode 110 of FIG. 5 with the anode, cathode, and oxide regions omitted. FIGS. 5, 6A, 6B, and 6C each include indicated reference X-Y-Z directions.

The ESD protection diode 110 includes an N-type region or layer 112, and a P-type region or layer 114. The N-type region or layer 112 is in contact with the P-type region or layer 114 to form a P/N junction 116 at an interface between the N-type region or layer 112 and the P-type region or layer 114. As seen in the side sectional views of FIG. 5 and FIG. 6B, the P/N junction 116 is non-planar. The ESD protection diode 110 further includes an N-type region contact 120 in contact with the N-type region 112, and a P-type region contact 122 in contact with the P-type region 114. As further shown only in FIG. 5, a cathode 124 is in contact with the N-type region contact 120, and an anode 126 is on contact in contact with the P-type region contact 122. In this nonlimiting illustrative example, a more heavily P-type doped region or layer 128 (i.e., P⁺-doped region or layer 128) is interposed between the P-type region 114 and the P-type region contact 122. The interposed P⁺-doped region or layer 128 reduces contact resistance between the P-type region 114 and the P-type region contact 122.

The N-type region or layer 112 and the P-type region or layer 114 are suitably silicon regions or layers, although other semiconductor materials are contemplated, such as Si₁₋ₓGeₓ, GaAs, or so forth. In the case of silicon, suitable N-type dopants for the N-type regions or layers of the ESD protection diode 110 include (but are not limited to) nitrogen (N), phosphorous (P), arsenic (As), or antimony (Sb); and suitable P-type dopants for the P-type regions or layers of the ESD protection diode 110 include (but are not limited to): boron (B), boron difluoride (BF₂), or indium (In). In one suitable fabrication approach, an N-type well 113 and deep N-type well 112 is formed by N-type dopant implantation, and the P-type region or layer 114 is formed by P-type counter-doping by P-type dopant implantation into the upper portion of the N-type well 113.

To provide the nonplanar P/N junction 116, an additional N-type doping implantation is performed to form deep N-type wells 130 (i.e., DNWs 130) in the P-type layer 114. This dopant implant step employs a photolithographically patterned mask to delineate the lateral areas of the deep N-type wells 130. The N-type wells 130 overlap or are contiguous with the N-type layer 112, and thus increase a surface area of the P/N junction 16. Although not shown, the deep N-type wells 130 of the embodiment of FIGS. 5, 6A, 6B, and 6C can have lateral layouts analogous to (for example) the illustrative example layouts for the N-type wells 30 shown in FIGS. 3A and 3B for the embodiment of FIGS. 1, 2A, 2B, and 2C, e.g., constituting a one-dimensional or two-dimensional array of deep N-type wells 130 in some examples, or layouts in which the N-type wells 130 do not form linear or rectilinear arrays. The deep N-type wells 130 may have rectangular perimeters analogous to those shown in FIGS. 3A and 3B for the deep N-type wells 30, or alternatively may have other perimeter shapes, such as oval, hexagonal, or so forth. The layout and perimeters of the deep N-type wells 130 are suitably delineated by the photolithography mask used to pattern the photoresist layer used in the deep N-type dopant implantation step that forms the deep N-type wells 130.

Referring back to FIGS. 5 and 6B, the illustrative N-type wells 130 have a rectangular cross-section in the X-Z plane. However, more generally the N-type wells 130 may have rounded shapes or other nonlinear shapes in the X-Z plane to provide the desired nonplanar P/N junction 16. In some embodiments, parameters of the deep dopant implantation (e.g., dose, beam current/implant time) or of an optional post-implantation anneal are adjusted to provide a desired depth distribution and hence shape in the X-Z plane of the deep N-type wells 130.

It will be appreciated that the foregoing is merely a nonlimiting illustrative example of one suitable fabrication sequence for forming the N-type region or layer 112 and 130 and P-type region or layer 114 of the ESD protection diode 110, and other fabrication workflows are contemplated such as forming the doped regions or layers 112 and 114 by epitaxial deposition and/or dopant diffusion (or counter-diffusion). The nonplanar P/N junction 116 of the ESD protection diode 110 advantageously provides a larger effective area for the P/N junction 116 without a concomitant increase in the die area or footprint of the ESD protection diode 110, thus advantageously increasing the on-state current and conductivity of the ESD protection diode 110 when it has entered its breakdown state. Described another way, the N-type region 112, 130 and the P-type region 114, 128 are interdigitated at the P/N junction 116 along at least one direction, and this interdigitation causes the P/N junction 116 to be nonplanar. Described yet another way, the N-type region 112, 130 and the P-type region 114, 128 are intermeshed in a transition region 132 (along the Z direction using the reference X-Y-Z directions; the transition region 132 is labeled only in FIG. 5), and this intermeshing causes the P/N junction 116 to be nonplanar.

With particular reference to FIGS. 5 and 6B, in the illustrative ESD protection diode 110, the P-type region 114 has a P-type doping gradient in which a P-type doping concentration increases with increasing distance away from the P/N junction 116. The illustrative N-type region 112 does not have a doping gradient; however, in other contemplated embodiments (not shown), the N-type region 112 could have an N-type doping gradient in which a N-type doping concentration increases with increasing distance away from the P/N junction 116. These doping gradient of the P-type region or layer 114 (and optionally also of the N-type region or layer) advantageously provides smaller leakage current for the ESD protection diode 110, and hence provides lower standby power. The gradient also advantageously increases the breakdown voltage of the ESD protection diode 110.

By way of nonlimiting illustration, in an example in which the material are silicon, the P-type doping concentration of the P⁺ layer 128 may be in a range of about 1×10¹⁵ cm⁻³ to about 9×10¹⁶ cm⁻³, the N-type doping concentration of the deep N-type layers or regions 112 and 130 may be in a range of about 1×10¹³ cm⁻³ to about 9×10¹⁴ cm⁻³. The P-type doping concentration of the P-type layer 114 may be in a range of about 1×10¹³ cm⁻³ to about 9×10¹⁴ cm⁻³, with the P-type doping distal from the P/N junction 116 being at or near the upper end of this range and the P-type doping proximate to the P/N junction 116 being at or near the lower end of this range. In some nonlimiting illustrative examples, the P-type doping concentration of the P-type layer 114 distal from the P/N junction 116 is about 90 times larger than the P-type doping of the P-type layer 114 proximate to the P/N junction 116. In some nonlimiting illustrative examples, the P-type doping concentration of the P-type layer 114 distal from the P/N junction 116 is at least 80 times larger than the P-type doping of the P-type layer 114 proximate to the P/N junction 116. In this nonlimiting illustrative example: the P⁺ layer 128 may have a thickness D4 in a range of 0.1 micron to 1 micron; the N-type region or layer 112 may have a thickness D5 in a range of 0.1 micron to 1 micron; the DNWs 130 may have a thickness D6 (corresponding to the transition 132 along the Z direction indicated only in FIG. 5) of 0.1 micron to 1 micron; and the P-type region or layer 114 may have a thickness D7 in a range of 0.1 micron to 1 micron. Again, there are merely nonlimiting examples, and doping concentrations and/or thicknesses outside of these illustrative ranges are contemplated. In this nonlimiting illustrative example: the DNWs 130 may have a width W2 of 0.1 micron to 1 micron, and the DNWs 130 may have a spacing S2 of 0.1 micron to 1 micron. Again, there are merely nonlimiting examples, and widths and/or spacings outside of these illustrative ranges are contemplated. More generally, the P/N junction 116 has a non-smooth junction topography - in the illustrative example this is achieved by the DNWs 130. In the nonlimiting illustrative example, D6/W2 (i.e., the ratio of the thickness to width of the DNW 130) is in a range of 0.1 to 10.

The N-type region contact 120 and P-type region contact 122 can, by way of some nonlimiting illustrative examples, be copper, aluminum, titanium, tantalum, cobalt, tungsten, various alloys thereof, polysilicon, a metal nitride such as TaN or TiN, and/or so forth. The choice of contact material may made based on design factors such as, by way of nonlimiting illustrative example, employing a same material for the contacts 20 and 22 as is used for source and drain contacts of FETs, finFETs, GAA-FETs, or the like used in the integrated circuit for which ESD protection is provided, or employing a same material for the contacts as is used for vias of a metallization stack formed during BEOL processing of the integrated circuit. The contact 120 to the N-type region or layer 112 and the contact 122 to the P-type region or layer 114 may be made of the same material, or may be made of different materials. The ESD protection diode 110 may include other features not shown, and/or features such as oxide regions 134 (shown only in FIG. 5) for delineating the active area of the ESD protection diode 110. The oxide regions 134 may, for example, be formed as STI regions.

As seen in FIG. 6A which shows a top view of the illustrative ESD protection diode 110 (with the anode 126 omitted), the P-type region contact 122 in contact with the P-type region 114, 128 is a single region. As seen in FIG. 6C which shows a bottom view of the illustrative ESD protection diode 110 (with the cathode 124 omitted), the N-type region contact 120 in contact with the N-type region 112 is a single region. In the illustrative example, the N-type region contact 120 is a single simply connected region which has no holes in it, and likewise the P-type region contact 122 is a single simply connected region which has no holes in it. These single-region contacts 120 and 122 advantageously reduce contact resistance as compared with having multiple contact regions, thereby increase the on-state electric current conducted by the ESD protection diode 110 which improves the efficacy of the ESD protection provided by the ESD protection diode 110.

Referring to FIGS. 5 and 6B, it is also seen that the N-type region 112, 130 and the P-type region 114, 128 (and hence also the P/N junction 116 therebetween) are disposed between the N-type region contact 120 and the P-type region contact 122. As shown only in FIG. 5, it is further seen that the N-type region 112, 130 and the P-type region 114, 128 (and hence also the P/N junction 116 therebetween) are disposed between the cathode 124 and the anode 126. Moreover, the N-type region contact 120 and the P-type region contact 122 are disposed between the cathode 124 and the anode 126. As previously discussed, this vertical arrangement places the cathode 124/N-type region contact 120 and the anode 126/P-type region contact 122 on opposite sides of the P/N junction 116, which advantageously reduces the electrical resistance (or, equivalently, increases the electrical conductivity) and increases the on-state current of the ESD protection diode 110. The vertical arrangement also reduces the height of the ESD protection diode.

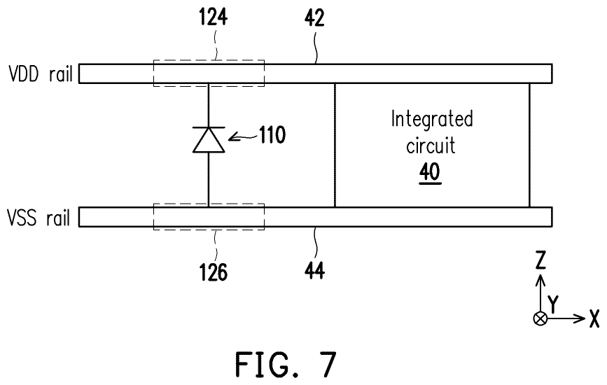

With continuing reference to FIG. 5 and with further reference now to FIG. 7, implementation according to one nonlimiting illustrative example of electrostatic discharge protection using the ESD protection diode 110 is described. FIG. 7 diagrammatically shows a side sectional view of the integrated circuit 40 (previously described with reference to FIG. 4) protected by the ESD protection diode 110 of FIG. 5. FIG. 7 also includes an indication of the reference X-Y-Z directions, indicating that the side sectional view of FIG. 7 is an X-Z plane. As also previously described with reference to FIG. 4, the first power distribution network 42 is disposed on a first (e.g., front) side of the integrated circuit 40, and the second power distribution network 44 is disposed on a second (e.g., back) side of the integrated circuit 40, opposite from the first side 42 of the integrated circuit.

In the embodiment of FIG. 7, the ESD protection diode 110 of FIG. 5 is connected between the VDD rail 42 and the VSS rail 44, and more particularly the cathode 124 is part of the VDD rail 42 and the anode 126 is part of the VSS rail 44. With the orientation shown in FIG. 7, the ESD protection diode 110 is reverse-biased since the cathode 124 is part of the VDD rail 42 and hence is at the VDD voltage and the anode 126 is part of the VSS rail 44 and hence is at the VSS voltage, where voltage VDD is greater than voltage VSS (i.e., VDD>VSS). By making the cathode 124 part of the VDD rail 42 and the anode 126 part of the VSS rail 44, electrical resistance of the connections of the ESD protection diode 110 are advantageously reduced by eliminating additional conductive paths from the rails to the anode and cathode, and the overall height of the ESD protection diode 110 including the cathode 124 and anode 126 is advantageously reduced.

In some embodiments, the ESD protection diode 110 is fabricated as a well diode, e.g. by forming the doped regions by dopant implantation into a base material such as a silicon wafer or the silicon layer of an SOI wafer. Such a well diode is readily integrated into IC manufacturing workflows employing planar FET technology, finFET technology, GAA-FET technology, combinations thereof, or so forth.

In the following, some further embodiments are described.

In a nonlimiting illustrative embodiment, an electrostatic discharge (ESD) protection device comprises a P-type region and an N-type region in contact with the P-type region to form a P/N junction at an interface between the P-type region and the N-type region. The P/N junction is non-planar.

In a nonlimiting illustrative embodiment, a method of forming an ESD protection diode includes: forming a P-type layer and an N-type layer with a P/N junction at an interface between the P-type layer and the N-type layer; and performing dopant implantation to form N-type wells in the P-type layer, wherein the N-type wells overlap or are contiguous with the N-type layer and increase a surface area of the P/N junction.

In a nonlimiting illustrative embodiment, a circuit comprises: an integrated circuit; an ESD protection diode having an anode and a cathode; a first power distribution network disposed on a first side of the integrated circuit; and a second power distribution network disposed on a second side of the integrated circuit opposite from the first side of the integrated circuit. The first power distribution network and the second power distribution network connect with the integrated circuit to electrically power the integrated circuit, and the ESD protection diode is disposed between the first power distribution network and the second power distribution network with the cathode being part of the first power distribution network and the anode being part of the second power distribution network and the back-side power distribution network.

In a nonlimiting illustrative embodiment, an ESD protection diode includes a P-type layer and an N-type layer in contact with the P-type layer to form a P/N junction at an interface therebetween. The P/N junction is non-planar. In one fabrication approach, dopant implantation is performed to form N-type wells in the P-type layer, which overlap or are contiguous with the N-type layer and increase a surface area of the P/N junction. The ESD protection diode may also have an anode and a cathode. The integrated circuit (IC) being protected may have first and second power distribution networks disposed on opposite sides of the IC that connect with the IC to electrically power the IC, and the ESD protection diode is disposed between the power distribution network s with the anode being part of one power distribution network and the cathode being part of the other power distribution network.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electrostatic discharge (ESD) protection device comprising:
a P-type region; and
an N-type region in contact with the P-type region to form a P/N junction at an interface between the P-type region and the N-type region;
wherein the P/N junction is non-planar.

2. The ESD protection device of claim 1, wherein the P/N junction is connected in reverse-bias across electrical conductors of an associated integrated circuit.

3. The ESD protection device of claim 2, further comprising:
an N-type region contact in contact with the N-type region;
a P-type region contact in contact with the P-type region;
an anode in contact with the N-type region contact; and
a cathode in contact with the P-type region contact;
wherein the P-type region and the N-type region are disposed between the N-type region contact and the P-type region contact and the P-type region and the N-type region are disposed between the anode and the cathode.

4. The ESD protection device of claim 3, wherein:
the N-type region contact is a single region; and
the P-type region contact is a single region.

5. The ESD protection device of claim 3, wherein the electrical conductors of the associated integrated circuit include a front-side power distribution network disposed on a front side of the associated integrated circuit and a back-side power distribution network disposed on a back side of the associated integrated circuit, and wherein:
the anode is part of one of the front-side power distribution network or the back-side power distribution network; and
the cathode is part of the other of the front-side power distribution network or the back-side power distribution network.

6. The ESD protection device of claim 1, wherein the P-type region has a P-type doping gradient in which a P-type doping concentration increases with increasing distance away from the P/N junction.

7. The ESD protection device of claim 6, wherein the N-type region has an N-type doping gradient in which an N-type doping concentration increases with increasing distance away from the P/N junction.

8. The ESD protection device of claim 1, wherein the N-type region and the P-type region are interdigitated at the P/N junction along at least one direction.

9. The ESD protection device of claim 1, wherein the N-type region and the P-type region are intermeshed in a transition region.

10. A method of forming an electrostatic discharge (ESD) protection diode, the method comprising:
forming a P-type layer and an N-type layer with a P/N junction at an interface between the P-type layer and the N-type layer; and
performing dopant implantation to form N-type wells in the P-type layer, wherein the N-type wells overlap or are contiguous with the N-type layer and increase a surface area of the P/N junction.

11. The method of claim 10, wherein the N-type wells formed by the dopant implantation are a one-dimensional or two-dimensional array of N-type wells.

12. The method of claim 10, wherein a P-type doping concentration of the P-type layer increases with increasing distance from the P/N junction.

13. The method of claim 12, wherein an N-type doping concentration of the N-type layer increases with increasing distance from the P/N junction.

14. A circuit comprising:
an integrated circuit;
an electrostatic discharge (ESD) protection diode having an anode and a cathode;
a first power distribution network disposed on a first side of the integrated circuit; and
a second power distribution network disposed on a second side of the integrated circuit opposite from the first side of the integrated circuit;
wherein the first power distribution network and the second power distribution network connect with the integrated circuit to electrically power the integrated circuit; and
wherein the ESD protection diode is disposed between the first power distribution network and the second power distribution network with the cathode being part of the first power distribution network and the anode being part of the second power distribution network and the back-side power distribution network.

15. The circuit of claim 14, wherein the ESD protection diode is connected by the cathode and anode in reverse-bias between the first power distribution network and the second power distribution network.

16. The circuit of claim 14, wherein the ESD protection diode includes:
a P-type layer; and
an N-type layer, a P/N junction being located at an interface between the P-type layer and the N-type layer;
wherein the P/N junction is nonplanar.

17. The circuit of claim 16, wherein the ESD protection diode further includes:
N-type wells in the P-type layer, wherein the N-type wells overlap or are contiguous with the N-type layer and cause the P/N junction to be nonplanar.

18. The circuit of claim 17, wherein at least one of the P-type layer and/or the N-type layer has a doping gradient in which a doping concentration increases with increasing distance away from the P/N junction.

19. The circuit of claim 14, wherein the ESD protection diode includes:
a P-type layer; and
an N-type layer in contact with the P-type layer to form a P/N junction at an interface between the P-type layer and the N-type layer;
wherein at least one of the P-type layer and/or the N-type layer has a doping gradient in which a doping concentration increases with increasing distance away from the P/N junction.

20. The circuit of claim 14, wherein the integrated circuit includes planar field effect transistors (FETs), finFETs, gate-all-around FETs (GAA-FETs), or a combination thereof.
